(19) United States
(12) Patent Application Publication
(10) Pub. No.: US 2008/0068227 A1
(43) Pub. Date: Mar. 20, 2008

(54) Input unit and electronic apparatus including same

(75) Inventor: Kenji Ogasawara, Osaka (JP)

Correspondence Address: EDWARDS ANGELL PALMER & DODGE LLP, P.O. BOX 55874, BOSTON, MA, 02205, US

(73) Assignee: Sharp Kabushiki Kaisha, Osaka (JP)

(21) Appl. No.: 11/901,846

(22) Filed: Sep. 19, 2007

(30) Foreign Application Priority Data
Sep. 19, 2006 (JP) 2006-252517
Oct. 12, 2006 (JP) 2006-279235

(51) Int. Cl. H03M 11/00

(52) U.S. Cl. 341/23

(57) ABSTRACT

The present invention provides an input unit wherein a password is hardly presumable even in the case where input keys or characters related to the input keys are peeped at by a third party. The input unit includes an operation panel 2, a display unit 9, an operating section 8 and a control section 7. The operating section 8 is a touch panel. The operating section 8 includes multiple input keys 10. The input key 10 has display sections 11 corresponding to codes formed thereon. The control section 7 displays the input keys 10 on a screen section 9a of the display unit 9, and displays the display sections 11 in the input keys 10. The control section 7 varies a status of the input keys 10 such as a color, a shape or a pattern according to an input mode.

### BACKGROUND OF THE INVENTION

1. Field of the Invention

The present invention relates to an input unit for inputting a code number and the like and an electronic apparatus including it.

2. Description of the Related Art

Recently, there are various electronic apparatuses under development, which include a security function for preventing leaks of information and unauthorized use. As for a representative security function, there is password authentication wherein a user is identified and use is authenticated by inputting a password which is a complicated character string with one-byte alphanumeric characters and symbols mixed therein. The password related to the password authentication is inputted from a mechanical or a touch-panel input unit.

As for a conventional input unit, there is a danger that what is inputted by pushing may be easily presumed by observing movement of fingers when inputting the password. In the case of a cash register or an outdoor ticket vending machine for instance, there is a high possibility of being peeped from behind or secretly filmed by a hidden CCD camera. For that reason, the conventional input unit has a problem that the password can be easily presumed even if input keys of the input unit are invisible to a third party.

Japanese Patent Laid-Open No. 2002-032176, Japanese Patent Laid-Open No. 2002-074508 and Japanese Patent Laid-Open No. 2004-102460 disclose an input unit and a method thereof wherein a change is made to a layout of the input keys or a layout of characters related to the input keys each time of use or for each individual user so that the third party can hardly sense the password.

As for the characters inputted from the input keys, however, one character per input key is inputted in any of Japanese Patent Laid-Open No. 2002-032176, Japanese Patent Laid-Open No. 2002-074508 and Japanese Patent Laid-Open No. 2004-102460. For that reason, there is a problem that, in the case where the characters related to the input keys are also peeped at by the third party, the password is presumed by the third party even if a change is made to the layout of the input keys or the layout of the characters related to the input keys.

Otherwise, it is also possible to authenticate the user twice. For instance, a department to which the user belongs is authenticated first and then the user is identified. In that case, operability is low since the user needs to input the password twice and input operation takes time.

In view of the problems, an object of the present invention is to provide an input unit wherein the password is hardly presumable even in the case where the input keys or the characters related to the input keys are peeped at by the third party, and an electronic apparatus including the input unit.

### SUMMARY OF THE INVENTION

To attain the object, the present invention is characterized by including: an input section including input keys having multiple codes; and a variable section for varying a status of the input keys in order to identify one code out of the multiple codes.

The codes are input values, such as alphabetic characters, hiragana, katakana, numeric characters, pictures and symbols inputted from the input keys. It is possible to input multiple different codes from one input key. The status of the input keys varies according to the code which is inputted. To be more specific, the input key varies to multiple statuses. A user can visually determine the code which can be inputted from the input key.

The variable section varies the entire input key. To be more precise, the variable section varies a color, a pattern and a shape of the input key.

The variable section varies a part of the input key. As a part of the input key, there is a display section corresponding to each code formed on the input key. Variable section varies the color and shape of the input key.

The variable section varies each of the multiple input keys to a different status. Each of the input keys is put in a different status according to the code which can be inputted. The user can easily distinguish the input key of the code desired to be inputted so as to be able to unmistakably input the code having alphabetic characters, numeric characters and the like mixed therein.

The variable section varies the status of the input key in predetermined timing. To be more specific, the status of the input key automatically varies. In the case of changing the status in arbitrary timing, a switching key for changing the status of the input key is provided. The variable section varies the status of the input key based on an input from the switching key. In that case, the status of the input key can be varied according to an intention of the user.

The variable section varies the status of the input key according to the input from the input key. To be more specific, the variable section predicts the code to be inputted next according to the input, and varies the status of the input key to the status corresponding to the predicted code.

The present invention includes notification section for notifying the user of an inputted code based on the status of the input key. The notification section allows the user to identify the code which can be inputted from a current input key so as not to mistake the input.

The present invention is characterized by including: a first input section; a second input section for inputting through operation by a user; a determination section for, upon a first input from the first input section, determining contents of the first input; and a variable section for varying a status of the second input section based on a determination result of the determination section.

If there is an input from the first input section, there will be an input from the second input section next. Input contents to be inputted next by the user are indicated by a determination of the determination section as to the input contents of the first input section. Before the user performs the operation, a variable section varies the status of the second input section so that the user can smoothly perform the input operation without being thereby interrupted. To be more specific, the determination section detects the input contents from the first input section, and predicts the input from the second input section based on the input contents from the first input section. The user has only to perform the input operation according to the varied second input section.

The first input section is characterized by inputting first authentication information, and the second input section is characterized by inputting second authentication information.

If the first authentication information is inputted, it is predictable that the second authentication information will be inputted next. Consequently, the variable section varies the status of the second input section so that the user can easily input the second authentication information.

The second input section is an input key whose status varies. As the status of the input key varies, it is possible to guide the user as to which input key should be operated. The user can easily perform the input operation, and operability is improved. If the first input section is rendered as an input key, it is sharable with the second input section. The first input section is not limited to the one for performing a direct input such as the input key, but may also be an input section for reading information or receiving information and inputting the information from outside.

The second input section is an input key whose status varies, and the variable section varies the entire input key. To be more precise, the variable section varies the color, pattern and shape of the input key. Or else, the variable section varies a part of the input key. The display section corresponding to multiple codes is formed on the input key. The variable section varies a part of the input key by varying the color and shape of the display section. Or else, the variable section varies the codes and also varies the display sections corresponding to the varied codes. In that case, the variable section varies the codes of adjacent input keys.

The second input section is an input key of which status varies, and the variable section is characterized by varying the status of the input key in predetermined timing after the input from the first input section. Normally, after the input from the first input section and before the input key is operated, the status of the input key is varied based on the input contents. The status of the input key may also be varied in arbitrary timing. In that case, the switching key for varying the status of the input key is provided. The user operates the switching key according to the next input operation. If the switching key is operated, the variable section varies the status of the input key. The variable section also varies the status of the input key when the input key is operated. Each time the user performs the input operation, the status of the input key is varied.

The variable section also varies the multiple input keys whose statuses vary to a different status as to each of the input keys. In the case where there are some kinds of inputs from the second input section, the user can be guided so as to perform an operating input without hesitation.

The above input unit can be provided to an electronic apparatus. As for the electronic apparatus, various kinds thereof are thinkable, such as a copier, a printer, a facsimile, a scanner or a complex apparatus combining two or more of those.

### BRIEF DESCRIPTION OF THE DRAWINGS

FIG. 1 is a block diagram of an input unit according to a first embodiment of the present invention;

FIG. 2 is a diagram showing input keys;

FIG. 3 is a diagram showing the input keys in colors corresponding to a numeric input mode;

FIG. 4 is a diagram showing the input keys in colors corresponding to an alphabetic input mode;

FIG. 5 is a diagram showing the input keys having a display section corresponding to the numeric input mode;

FIG. 6 is a diagram showing the input keys having the display section corresponding to the alphabetic input mode;

FIG. 7 is a diagram showing the input keys having a notification key in the numeric input mode;

FIG. 8 is a diagram showing the input keys having the notification key in the alphabetic input mode;

FIG. 9 is a diagram showing the input keys having a switching key in the numeric input mode;

FIG. 10 is a diagram showing the input keys having the switching key in the alphabetic input mode;

FIG. 11 is a diagram showing the input keys varied in different statuses;

FIG. 12 is a block diagram of an image processing apparatus including the input unit according to a second embodiment;

FIG. 13 is a diagram showing the input keys;

FIG. 14 is a diagram showing the input keys in the case where upper alphabetic characters are replaced;

FIG. 15 is a diagram showing the input keys in the case where lower alphabetic characters are replaced;

FIG. 16 is a diagram showing the input keys varied to the colors corresponding to the numeric input mode;

FIG. 17 is a diagram showing the input keys varied to the colors corresponding to the alphabetic input mode for inputting the upper alphabetic characters;

FIG. 18 is a diagram showing the input keys varied to the colors corresponding to the alphabetic input mode for inputting the lower alphabetic characters;

FIG. 19 is a diagram showing the input keys varied to the display section corresponding to the numeric input mode;

FIG. 20 is a diagram showing the input keys varied to the display section corresponding to the alphabetic input mode for inputting the upper alphabetic characters;

FIG. 21 is a diagram showing the input keys varied to the display section corresponding to the alphabetic input mode for inputting the lower alphabetic characters;

FIG. 22 is a diagram showing the input keys having the switching key in the numeric input mode;

FIG. 23 is a diagram showing the input keys having the switching key in the alphabetic input mode for inputting the upper alphabetic characters;

FIG. 24 is a diagram showing the input keys having the switching key in the alphabetic input mode for inputting the lower alphabetic characters;

FIG. 25 is a flowchart of authentication operation; and

FIG. 26 is a flowchart on varying a status of the input keys.

### DETAILED DESCRIPTION OF THE PREFERRED EMBODIMENTS

### [First Embodiment]

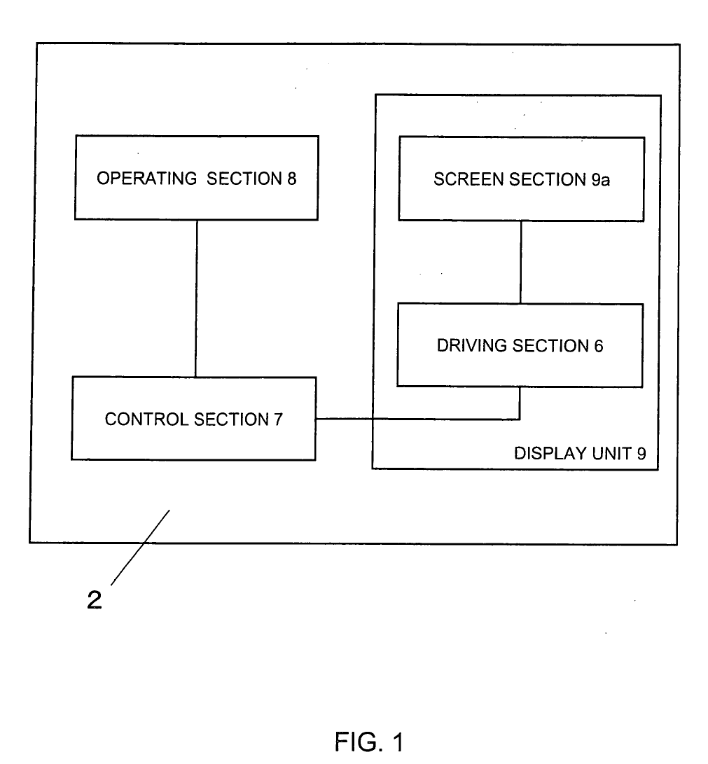

Hereafter, an input unit according to a first embodiment of the present invention will be described with reference to the drawings. The input unit of this embodiment is mounted on an electronic apparatus to which a user performs an operating input. As shown in FIG. 1, the input unit includes on an operation panel 2 a display unit 9 for displaying an operation screen, an operating section 8 for input operation and a control section 7 for processing inputted operational information and authentication information.

The display unit 9 includes a screen section 9a for displaying keys, marks and the like which guide the input and a driving section 6 for controlling a drive of the screen section 9a. The screen section 9a is formed on the operation panel 2. The driving section 6 controls the drive of the screen section 9a to display the keys, marks and the like thereon based on an instruction from the control section 7.

The operating section 8 is a known touch panel for touching the keys, marks and the like displayed on the screen section 9a with the tip of a finger and inputting a code. Multiple input keys 10 constituting the operating section 8 are formed on the screen section 9a.

The control section 7 is a CPU for controlling overall operation of the input unit. The control section 7 controls the driving section 6 so as to display the input keys 10 on the screen section 9a according to operating conditions of an electronic apparatus. The driving section 6 displays the multiple input keys 10 in a matrix state on the screen section 9a.

The input key 10 includes multiple codes. To be more specific, different codes can be inputted with one input key 10. The codes are character information, such as alphabetic characters, hiragana, katakana, numeric characters, pictures and symbols. Display section 11 corresponding to each code is formed within the input key 10. There are multiple display sections 11 according to the codes.

The input unit includes multiple input modes in order to input the codes. The control section 7 switches the input mode according to the operating conditions. If the input keys 10 are operated, the operating section 8 outputs a code signal to the control section 7. The control section 7 determines the code from the code signal according to the input mode.

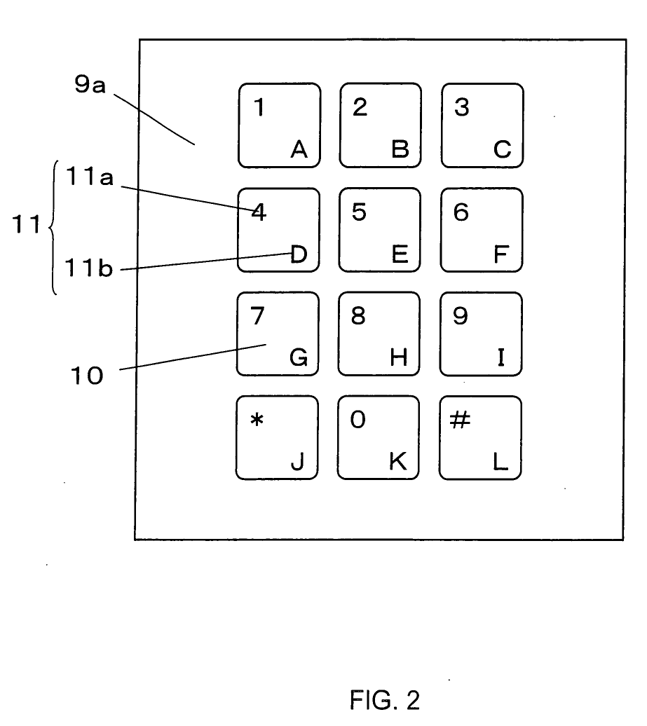

To be more precise, in the case where one input key 10 has two codes of the numeric character and alphabetic character as shown in FIG. 2, the input key 10 has a first display section 11a with a numeric character drawn and a second display section 11b with an alphabetic character drawn formed thereon. The control section 7 switches between a number input mode for identifying an inputted code as a numeric character and an alphabet input mode for identifying the code as an alphabetic character. When in the number input mode, the control section 7 determines the input from the input key 10 as a numeric character. When in the alphabet input mode, the control section 7 determines the input from the input key 10 as an alphabetic character.

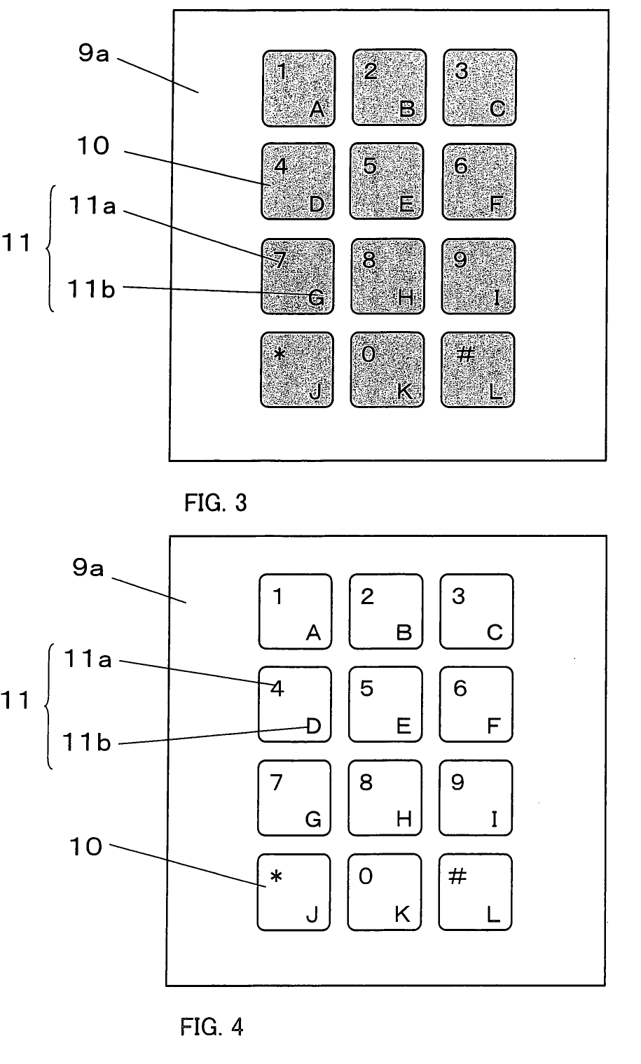

The control section 7 includes variable section for varying a status of the input keys 10 according to each input mode. The variable section controls the drive of the display unit 9 so as to vary the status of the entire input keys 10. To be more precise, the variable section varies the color of each of the input keys 10 according to the input mode as shown in FIGS. 3 and 4. In the case of the number input mode for instance, the color of the input key 10 is rendered blue. In the case of the alphabet input mode, the color of the input key 10 is rendered yellow. Thus, the user is allowed to easily recognize which input mode is current.

In the case where the user wants to input a numeric character, the user operates a desired input key 10 when the input keys 10 are blue as shown in FIG. 3. The control section 7 recognizes that the input keys are in the number input mode and determines the code as the code of a numeric character. In the case where the user wants to input an alphabetic character, the user operates a desired input key 10 when the input keys 10 are yellow as shown in FIG. 4. The control section 7 recognizes that the input keys are in the alphabet input mode and determines the code as the code of an alphabetic character.

Thus, the input keys 10 are put in the status according to the input mode. The user can know which code should be inputted at a glance. On the other hand, a third party can know which input keys 10 have been operated but cannot know the inputted code. Therefore, it is possible to improve operability for the user and enhance security.

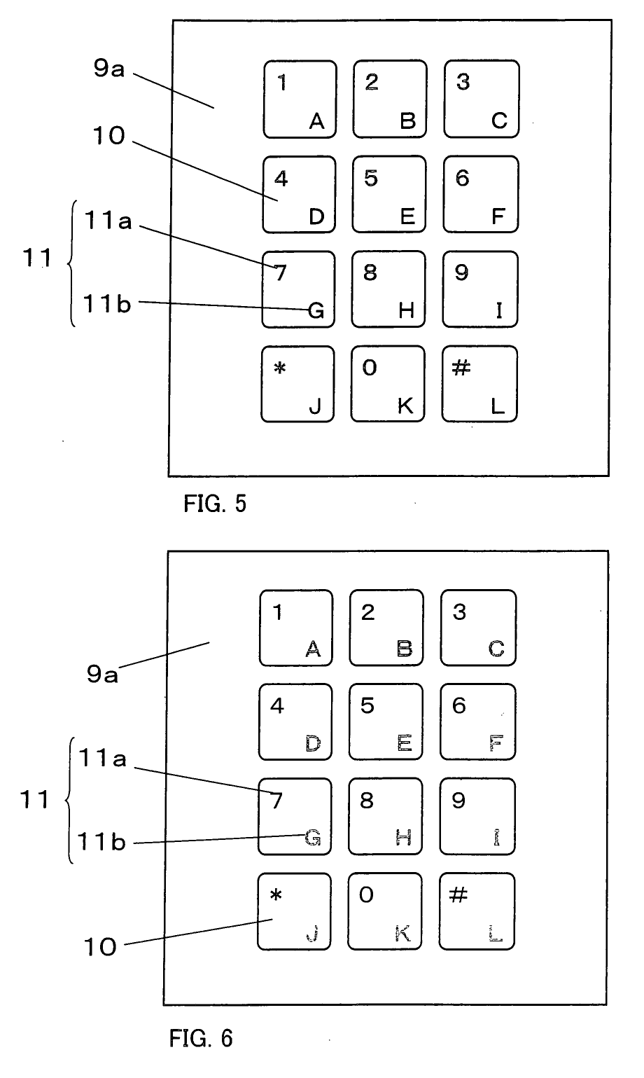

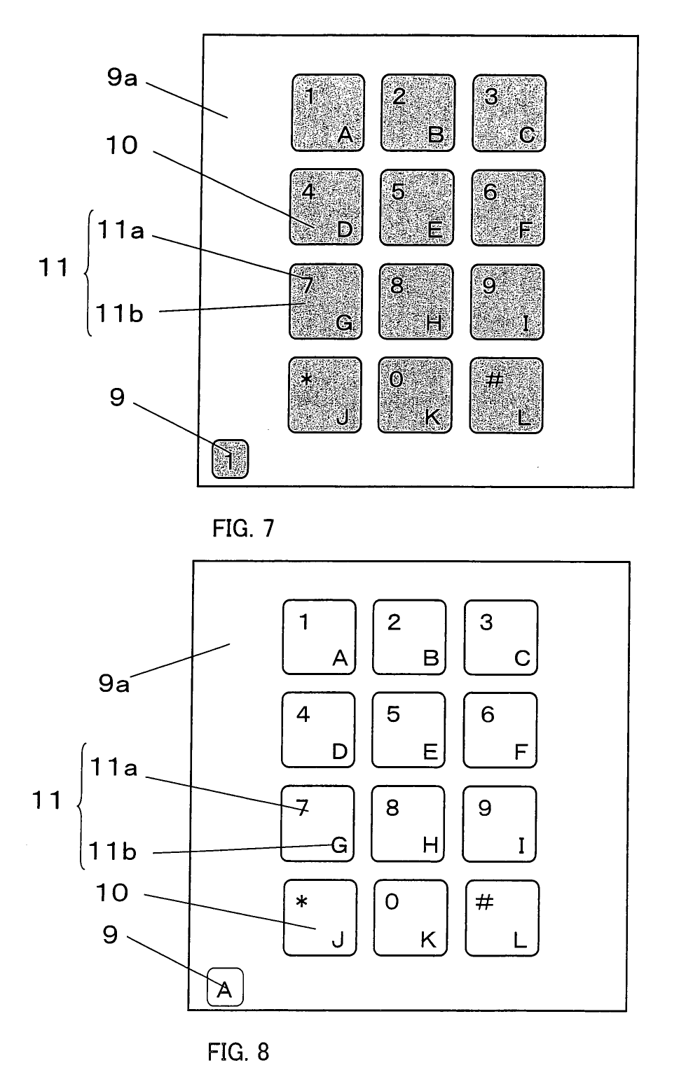

As another form of the input key 10, the variable section varies a part of the input key 10. To be more specific, the variable section varies the status of the display sections 11 constituting a part of the input key 10. For instance, as shown in FIGS. 5 and 6, it varies the color of the display sections 11 of the input keys 10 according to the input mode. To be more precise, in the case of the number input mode, the color of the display section 11a related to the numeric character is rendered red and the color of the display section 11b related to the alphabetic character is rendered black. In the case of the alphabet input mode, the color of the display section 11b related to the alphabetic character is rendered red and the color of the display section 11a related to the numeric character is rendered black.

The control section 7 includes a notification section for notifying the user of which input mode is current. The notification section performs notification by displaying the current input mode. The notification section controls the drive of the display unit 9 to display a notification key 9 representing the input mode on the screen section 9a. The notification key 9 allows the user to easily recognize which input mode is current.

Here, the notification key 9 should be displayed so as not to be peeped at by a third party. In the case where the notification key 9 is peeped at by a third party, it is knowable which input mode is used for the input so that a password may be sensed. Therefore, the notification key 9 is displayed to be smaller than the input key 10 at the lower left of the screen section 9a. The user can cover over the notification key 9 with his or her hand. It is thereby possible to prevent the input mode from being known by the third party.

The input mode is switched in predetermined timing. The control section 7 measures time with a timer so as to switch the input mode when predetermined time elapses. For that reason, the user needs to finish the input within the predetermined time. However, the current input mode becomes hardly knowable to the third party.

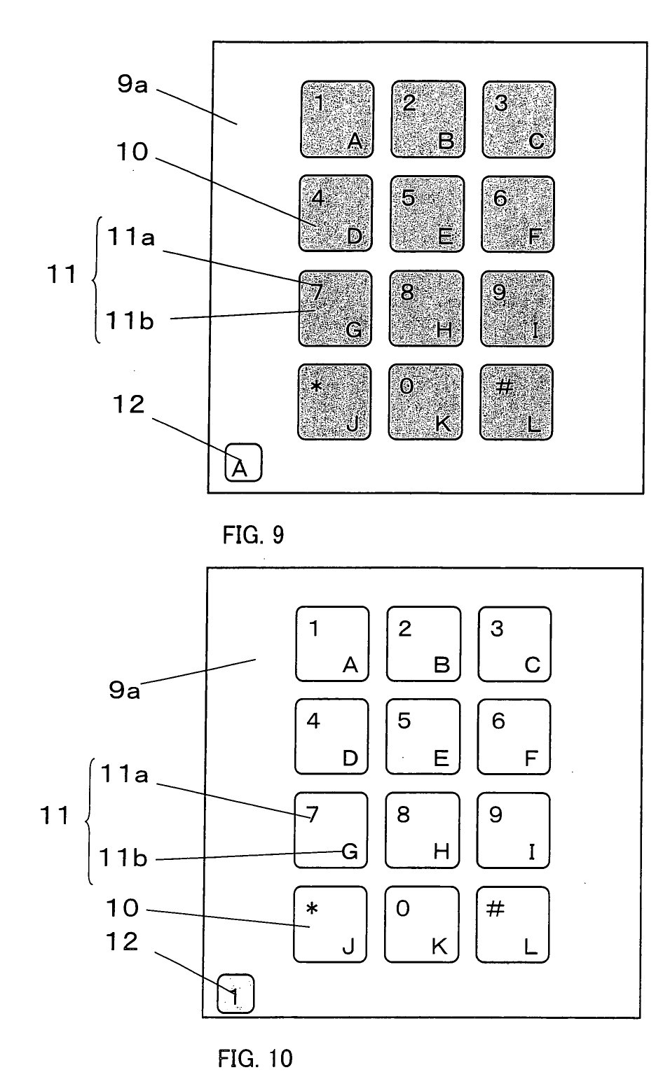

In view of convenience for the user, it is desirable that the user arbitrarily switch the input mode. Therefore, as shown in FIGS. 9 and 10, the control section 7 controls the drive of the display unit 9 to form a switching key 12 for varying the status of the input keys 10. The switching key 12 has the color and character representing an input mode different from the current input mode. When in the number input mode, the switching key 12 is yellow and has the alphabetic character as shown in FIG. 9. When in the alphabet input mode, the switching key 12 is blue and has the numeric character as shown in FIG. 10.

If the user operates the switching key 12, the control section 7 switches the input mode. At the same time, the control section 7 varies the status of the input keys 10. It also varies the mode of the switching key 12 to another input mode.

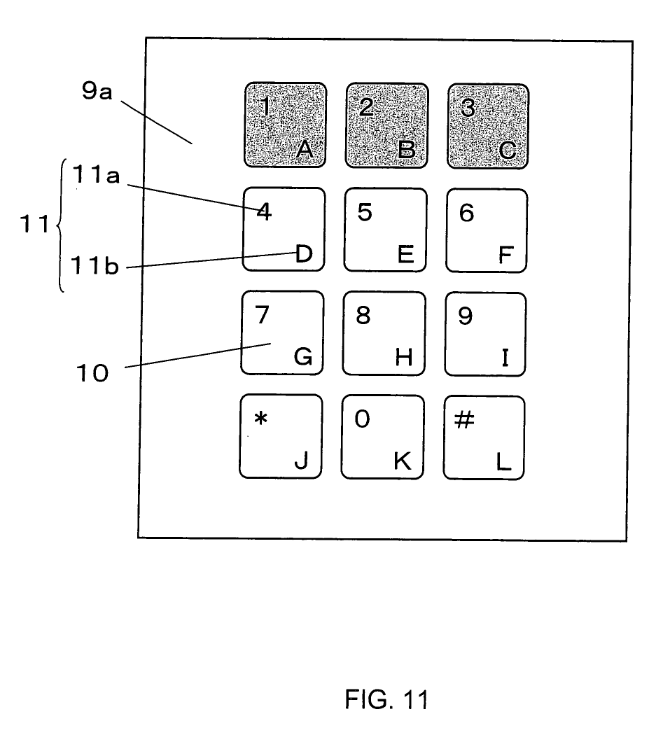

As another form of the input keys 10, the variable section puts each of the input keys 10 in a different status as shown in FIG. 11. The variable section renders the color of some of the input keys 10 blue correspondingly to the number input mode, and renders the color of the rest of the input keys 10 yellow correspondingly to the alphabet input mode. In that case, the control section 7 determines the code signal from a blue input key 10 as a numeric character, and determines the code signal from a yellow input key 10 as an alphabetic character. Thus, the control section 7 can input two kinds of code without switching the input mode with the switching key 12.

In that case, the user can input the two kinds of code. To be more specific, the numeric characters and alphabetic characters can be inputted without switching the input mode. For that reason, input time can be reduced in the case where the password has the alphabetic characters and the numeric characters mixed therein. The user can operate the input keys 10 so as not to give time to be peeped at by the third party.

The color of the input keys 10 or the color of the display sections 11 is randomly set by the control section 7. In that case, the control section 7 displays the notification key 9. It is also possible for an authorized user such as a manager to set the color.

The input unit of this embodiment is mounted on an image processing apparatus. In the case of copying a document which can be copied only by a specific user of confidential documents or the like, the user inputs the password in order to be authenticated for use. First, the control section 7 displays a password input screen upon detecting an operating input for starting password authentication from the user. In that case, the user selects the input mode according to the code to be inputted. In the case where the user selects the number input mode, the variable section displays the input keys 10 in blue. In the case where the user selects the alphabet input mode, the variable section displays the input keys 10 in yellow.

In the case of mixedly inputting the numeric characters and alphabetic characters, the user operates the switching key 12 according to the code to be inputted. The control section 7 switches the input mode and varies the status of the input keys 10.

Once the user finishes inputting the password, the control section 7 recognizes the password based on the inputted code. The control section 7 determines whether the inputted password matches with the password registered in advance. If the passwords match, the control section 7 authenticates the user as the specific user and permits copying. In the case where the passwords do not match, the control section 7 determines that the user is not the specific user, gives a notice to that effect on the display unit 9 and then inhibits the copying.

### [Second Embodiment]

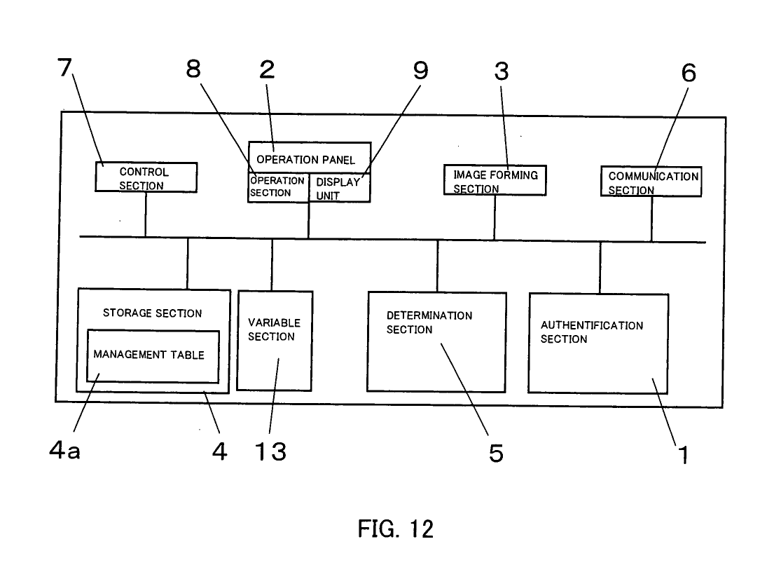

Hereafter, an input unit according to a second embodiment of the present invention will be described based on the drawings. The input unit of this embodiment is mounted on an electronic apparatus to which the user performs an operating input. As shown in FIG. 12, the electronic apparatus is an image processing apparatus which includes an image reading section for reading a document and inputting image data, an operation panel 2 for receiving an input of the user, an image forming section 3 for printing inputted image data, a storage section 4 composed of a hard disk drive for storing the image data, a communication section 6 for performing data communication with external apparatuses and a control section 7 composed of a CPU for controlling overall operation of the apparatus.

The image reading section functions as image data input section for inputting the image data, and includes an image pickup device such as a CCD and a document detection sensor for detecting a document which is set on a document tray or an automatic document feeder (ADF). The image data of an image which has been read by the CCD is outputted to the image forming section 3.

The image forming section 3 functions as processing section for processing the image data. To be more precise, the image forming section 3 outputs the inputted image data to a printing section so as to print the image on a recording sheet. The operation panel 2 includes an operating section 8 composed of various fixed keys and a display unit 9 such as a liquid crystal display. The display unit 9 includes a screen section 9a and a driving section for controlling the drive of the screen section 9a. The screen section 9a includes a known touch panel, where input keys 10 for operating the input are formed.

The storage section 4 includes a management table 4a for storing control information and setup information on the entire unit, authentication information on each individual user and the like.

The communication section 6 is connected to a router, a switching hub and the like via a LAN cable so as to be connected to a network formed by external terminals, such as personal computers and servers. The network is connected to the Internet via a communication line, such as a telephone line network or an optical fiber. The communication section 6 transmits and receives data to and from the external terminals within the network, and transmits and receives data and e-mail to and from the external terminals outside through the Internet. Furthermore, the communication section 6 performs Internet facsimile communication with a facsimile apparatus through the Internet.

The communication section 6 also receives and inputs the image data from the external apparatuses such as the external terminals and facsimile apparatuses. Upon inputting the image data from the external apparatuses, the communication section 6 simultaneously receives the input of an operational instruction. Furthermore, the communication section 6 executes a process of transmitting the image data to the external apparatuses and thereby functions as processing section.

The image processing apparatus includes an authentication section 1 for authenticating the user. If the user inputs the authentication information such as a password or an ID from the input keys 10 of the operating section 8 or the screen section 9a, the authentication section 1 authenticates the user based on the inputted authentication information. The management table 4a has the authentication information on the user registered therein in advance. The authentication section 1 checks the inputted authentication information against the registered authentication information so as to check whether the user is the registered user. The user is authenticated by checking that the user is the registered user. The authentication information is not limited to the information directly inputted by the user but may also be the authentication information read from a storage medium such as an IC card or biologic information such as a fingerprint. In that case, the image processing apparatus includes a communication interface such as a USB or a biologic information reader.

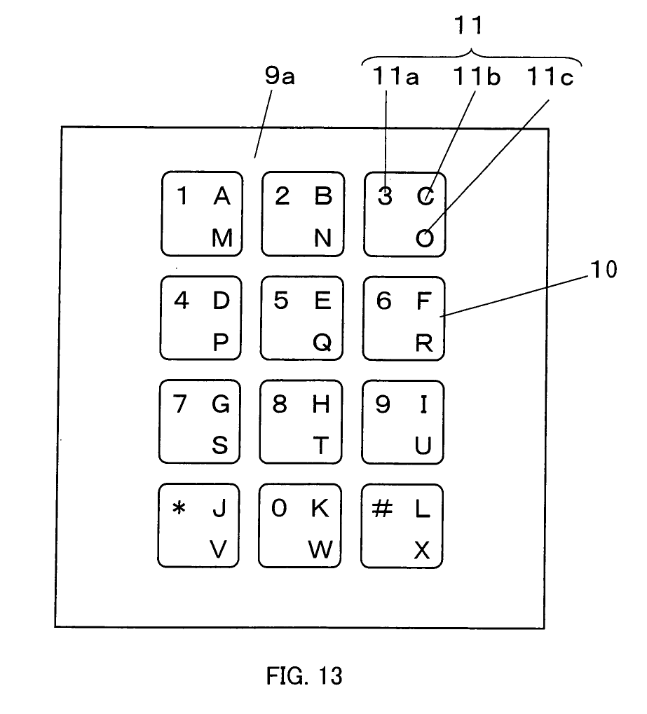

As shown in FIG. 13, the input key 10 includes multiple codes. To be more specific, different codes can be inputted with one input key 10. The codes are character information, such as alphabetic characters, hiragana, katakana, numeric characters, pictures and symbols. Display sections 11 corresponding to each code are formed within the input key 10. There are multiple display sections 11 according to the codes.

The control section 7 controls the driving section so as to display the input keys 10 on the screen section 9a according to the operating conditions. The driving section displays the multiple input keys 10 in a matrix state on the screen section 9a.

The input unit mounted on the image processing apparatus is composed of the input section such as the operating section 8, the input keys 10 of the screen section 9a, the communication section 6 and the communication interface, and the control section 7 for outputting an operation command to each of the sections of the image processing apparatus according to the input operations.

Here, the input section includes first input section for performing the first input operation and second input section for performing the input operation next. And the input unit includes a determination section 5 for determining input contents of the first input section and a variable section 13 for changing the status of the second input section based on the input contents.

The first input section and the second input section are the input keys 10. The determination section 5 and the variable section 13 are operated by the control section 7. The determination section 5 detects the contents inputted by the input operation of the input key 10, and predicts the contents inputted by the input key 10 undergoing the input operation next. The determination section 5 determines what processing will be performed based on the input contents from the input keys 10 so as to predict the next input contents in conjunction with the processing. The variable section 13 controls the driving section based on the predicted input contents and varies the status of the input keys 10. It is possible, by this change, to guide the user not to take time in the input operation when the user operates the input keys 10.

The status of the input key 10 is varied by varying the display sections 11 formed on the input key 10. To be more specific, the input key includes multiple input modes in order to input the codes from the input key 10. The control section 7 switches the input mode according to the operating conditions. If the input keys 10 are operated, the screen section 9a outputs a code signal to the control section 7. The control section 7 determines the code from the code signal according to the input mode.

To be more precise, in the case where one input key 10 has three codes of the numeric character and alphabetic characters as shown in FIG. 13, the input key 10 has a first display section 11a with a numeric character drawn, and a second display section 11b and a third display section 11c with an alphabetic character drawn formed thereon. Here, the second display section 11b is the code described in the upper stage of the input key 10. The third display section 11c is the code described in the lower stage of the input key 10.

The control section 7 switches between the number input mode for identifying an inputted code as a numeric character and the alphabet input mode for identifying the code as an alphabetic character. When in the number input mode, the control section 7 determines the input from the input key 10 as a numeric character. When in the alphabet input mode, the control section 7 determines the input from the input key 10 as an alphabetic character. In that case, the control section 7 determines whether it is the alphabet input mode of the upper stage or the alphabet input mode of the lower stage.

When the authentication information on the user is inputted from the input keys 10 as the first input operation, the status of the input keys 10 is varied according to the user authenticated by the authentication section 1. In that case, the determination section 5 recognizes the processing contents from the inputted authentication information and predicts the code to be inputted next. And the control section 7 exerts control to vary the status of the input keys 10 correspondingly to the predicted code.

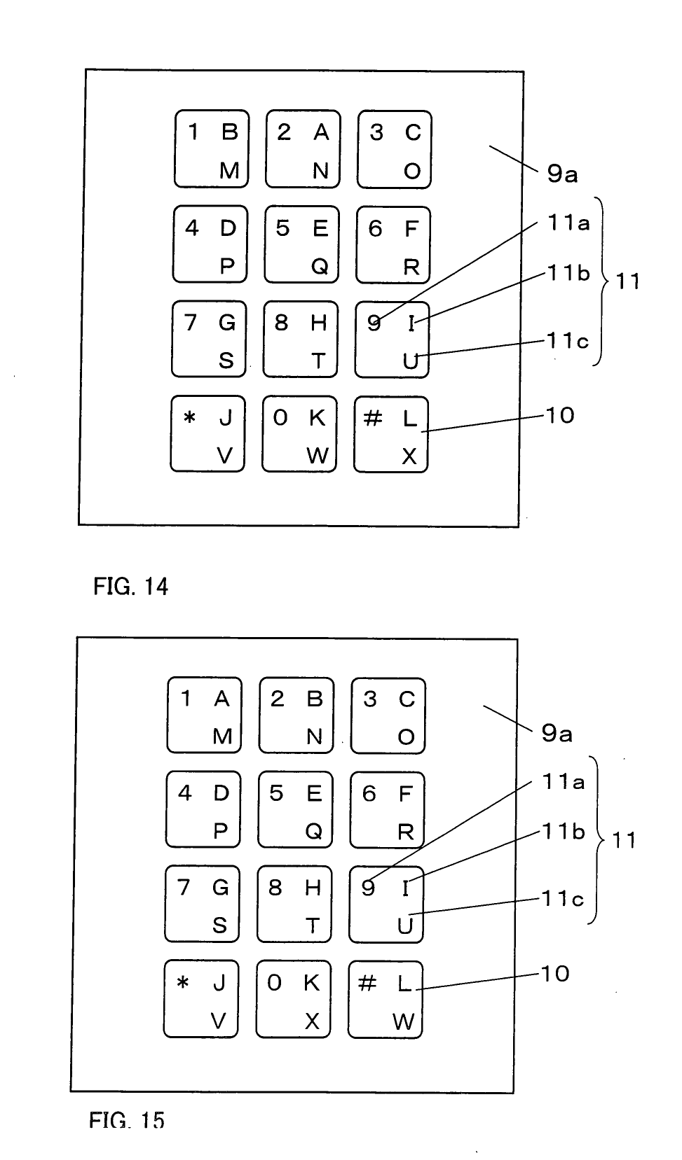

As shown in FIGS. 14 and 15, a part of the input keys 10 is varied according to the user authenticated by the authentication section 1. To be more specific, the codes of the input keys 10 are varied according to the authenticated user, and an variation is made to the status of the display sections 11 constituting a part of the input keys 10.

For instance, in the case where there are two passwords “A1345” and “1345A” predicted as the authentication information to be inputted next, “A” and “1” are normally allocated to the same input key 10 as shown in FIG. 2 so that the control section 7 cannot determine whether the input from the input key 10 is the input of “A” or the input of “1.” Thus, varies are made to the code of the input keys 10 and the status of the display sections 11 related to that code according to the predicted password.

As shown in FIG. 14, a variation is made to allocation of the alphabetic character “A” of the upper stage of the input key 10 on the top of the left row and the alphabetic character “B” of the upper stage of the input key 10 on the top of the middle row. Also, the display section 11b related to the alphabetic character of the upper stage of the input key 10 on the top of the left row is varied to “B,” and the display section 11b related to the alphabetic character of the upper stage of the input key 10 on the top of the middle row is varied to “A.” Thus, the control section 7 can determine whether the user has inputted “A” or “1.” The user can clearly check which password is being inputted. It is possible to reduce input operation errors of the user, such as pushing a wrong input key 10.

In the case of other passwords such as “W0123” and “0123W,” as shown in FIG. 15, a change is made to allocation of the alphabetic character “W” of the lower stage of the input key 10 on the bottom of the middle row and the alphabetic character “X” of the lower stage of the input key 10 on the bottom of the right row. Also, the display section 11c related to the alphabetic character of the lower stage of the input key 10 on the bottom of the middle row is varied to “X,” and the display section 11c related to the alphabetic character of the lower stage of the input key 10 on the bottom of the right row is varied to “W.” It is also possible to change the display of the input key 10 according to the character at the end of the password instead of changing the display of the input key 10 according to the first character of the password.

Thus, the code to be inputted next is predicted according to the authentication information inputted earlier so as to vary the status of the input keys 10 according to the code. In that case, the variable section 13 varies the display sections 11 of adjacent input keys 10. For that reason, the user does not need to look for where the varied code is. On the other hand, a third party can know which input keys 10 have been operated but cannot know the inputted code. Therefore, it is possible to improve operability for the user and enhance security.

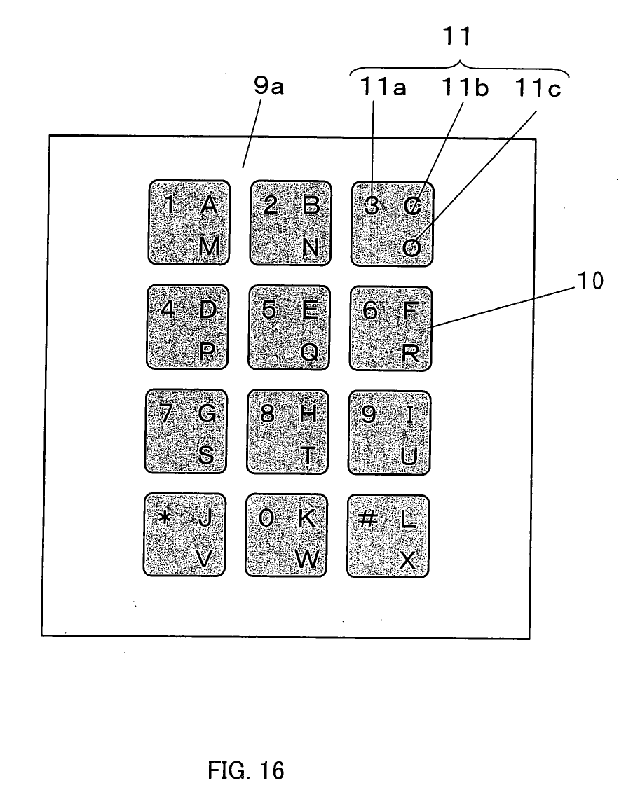

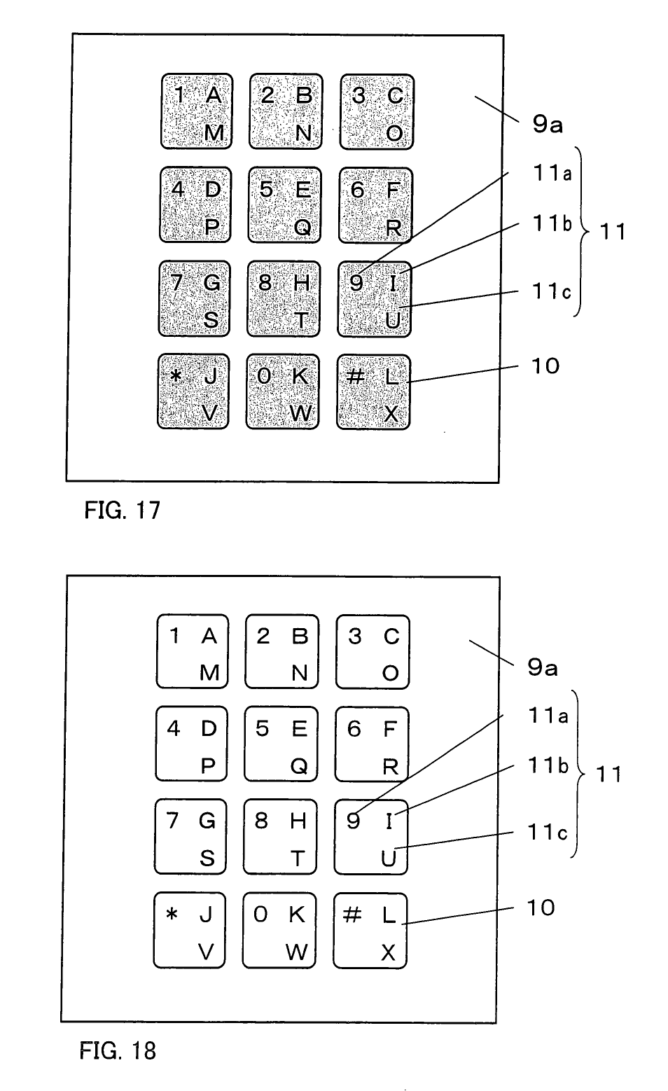

As another form of the change of the input key 10, the entire input keys 10 are varied. As shown in FIGS. 16 to 18, the color of each of the input keys 10 is varied according to the input mode. For instance, in the case of the number input mode, the color of the input keys 10 is rendered blue as shown in FIG. 16. The user operates desired input keys 10. The control section 7 recognizes that the input mode is the number input mode and determines it to be a numeric code. In the case of the alphabet input mode in the upper stage, the color of the input keys 10 is rendered yellow as shown in FIG. 17. The user operates the desired input keys 10. The control section 7 recognizes that the input mode is the alphabet input mode in the upper stage and determines it to be an alphabetic code in the upper stage of the input key 10. In the case of the alphabet input mode in the lower stage, the color of the input keys 10 is rendered pink as shown in FIG. 18. The user operates the desired input keys 10. The control section 7 recognizes that the input mode is the alphabet input mode in the lower stage and determines it to be an alphabetic code in the lower stage of the input key 10.

Thus, the input keys 10 are put in the status according to the input mode. The user can know which code should be inputted at a glance, which improves the operability. On the other hand, a third party can know which input keys 10 have been operated but cannot know the inputted code.

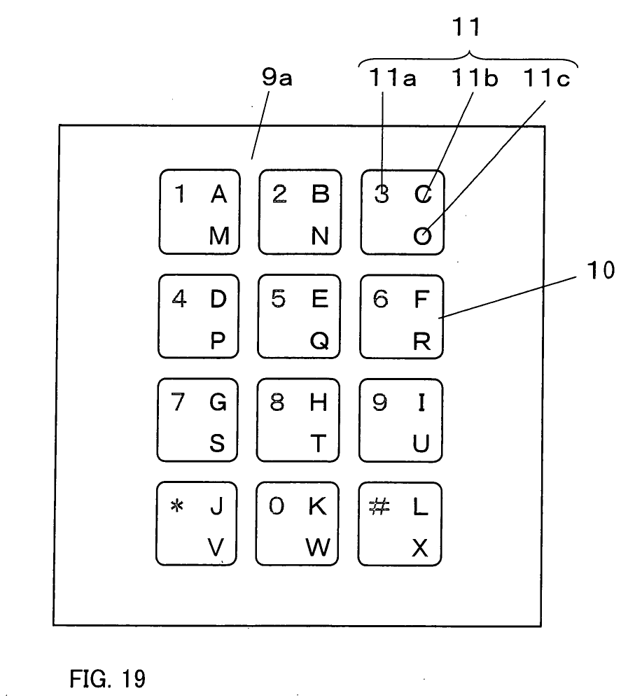

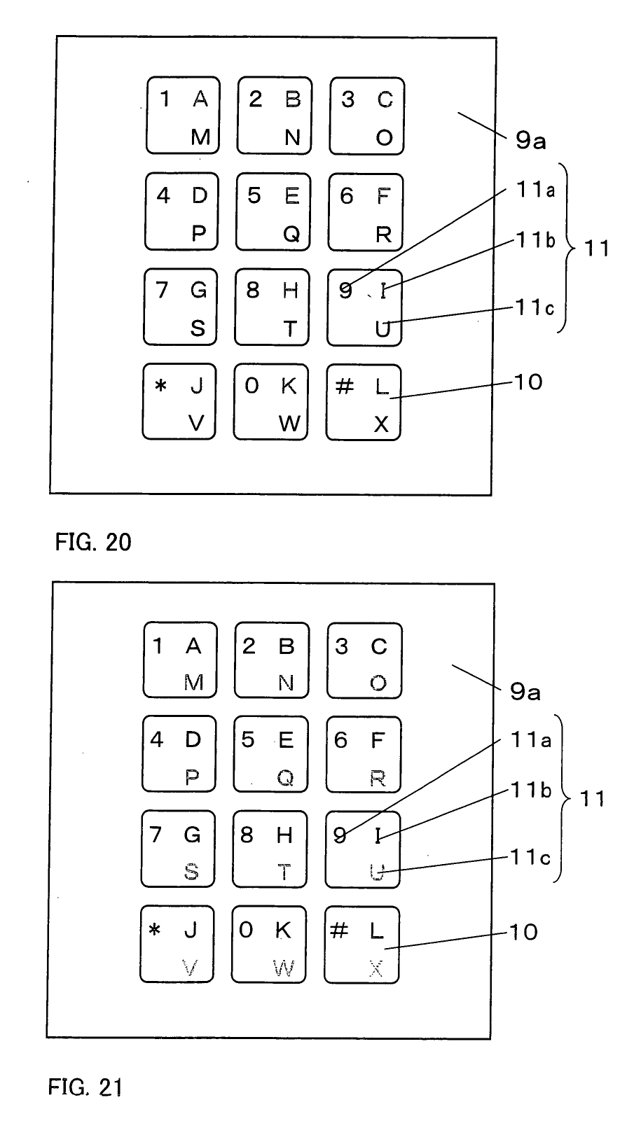

As another form of the change of the input key 10, the variable section 13 varies a part of the input key 10. To be more specific, the variable section 13 varies the status of the display sections 11 of the input key 10. For instance, it varies the color of the display sections 11 of the input key 10 according to the input mode. As shown in FIG. 19, in the case of the number input mode, the color of the display section 11a related to the numeric character is rendered red and the color of the display sections 11b and 11c related to the alphabetic character in the upper and lower stages is rendered black. As shown in FIG. 20, in the case of the alphabet input mode in the upper stage, the color of the display section 11b related to the alphabetic character in the upper stage is rendered red and the color of the display sections 11a and 11c related to the numeric character and the alphabetic character in the lower and upper stage is rendered black. As shown in FIG. 21, in the case of the alphabet input mode in the upper stage, the color of the display section 11c related to the alphabetic character in the lower stage is rendered red and the color of the display sections 11a and 11b related to the numeric character and the alphabetic character in the upper stage is rendered black.

The control section 7 includes notification section for notifying the user of which input mode is current when there are multiple input modes as above. The notification section performs notification by displaying the current input mode. The notification section controls the drive of the display unit 9 to display a notification key representing the input mode on the screen section. The notification key allows the user to easily recognize which input mode is current.

Here, the notification key should be displayed so as not to be peeped at by a third party. In the case where the notification key is peeped at by a third party, it is knowable which input mode is used for the input so that a password may be sensed. Therefore, the notification key is displayed to be smaller than the input key 10 at the lower left of the screen section. The user can cover over the notification key with his or her hand. It is thereby possible to prevent the input mode from being known by the third party.

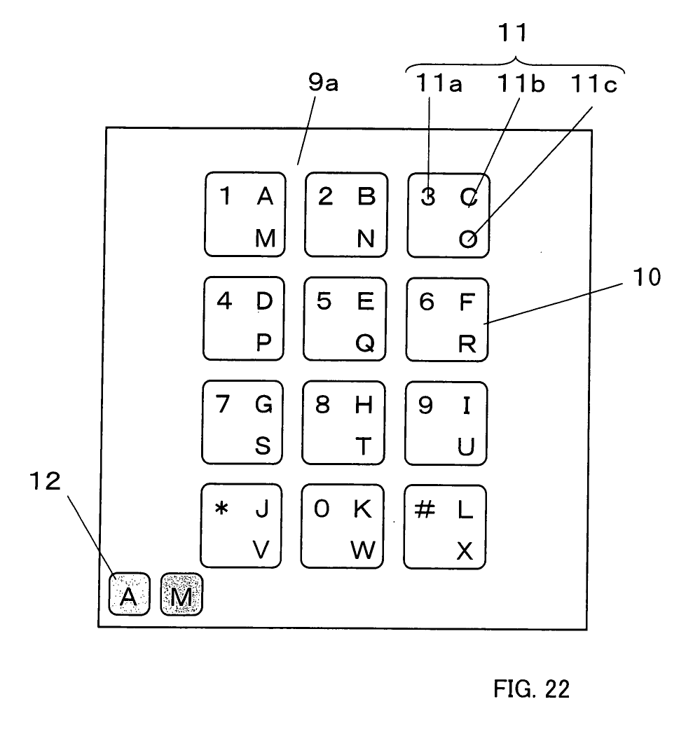

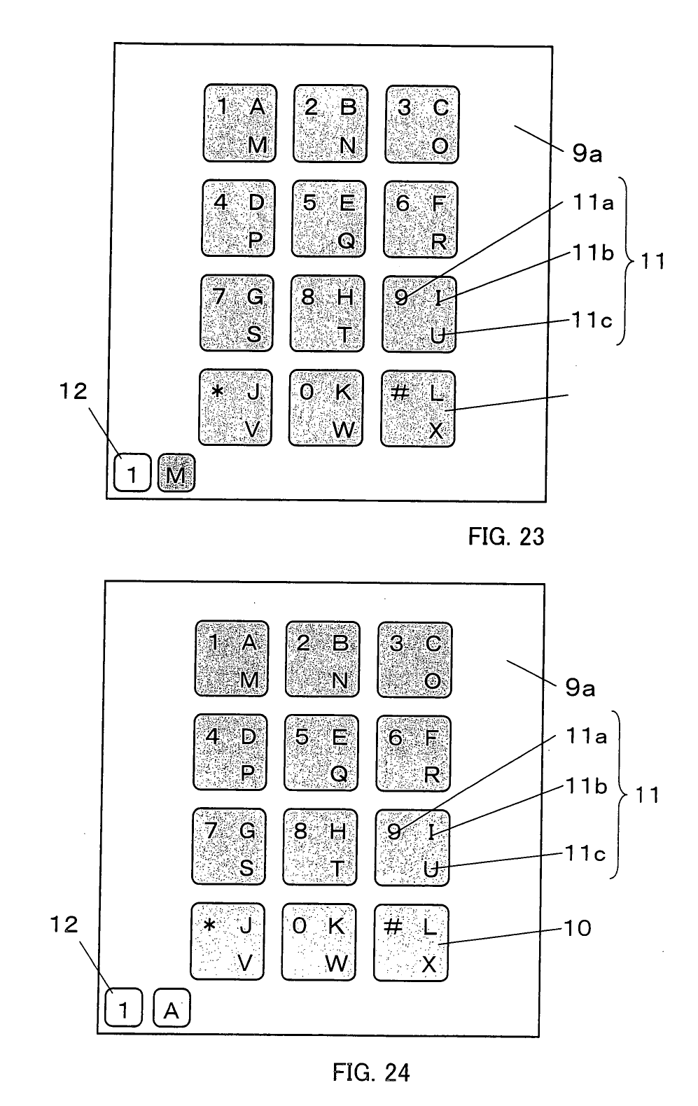

When inputting the password combining multiple codes, the input mode is switched in predetermined timing. As shown in FIGS. 22 to 24, the control section 7 controls the drive of the display unit 9 so as to form a switching key 12 for varying the status of the input keys 10. The switching key 12 has the color and character representing an input mode different from the current input mode. When currently in the number input mode, the switching key 12 for the alphabetic character in the upper stage is yellow, and the switching key 12 for the alphabetic character in the lower stage is blue as shown in FIG. 22. When in the alphabet input mode for inputting the alphabetic character in the upper stage, the switching key 12 for the alphabetic character in the lower stage is blue, and the switching key 12 for the number input mode is pink as shown in FIG. 23. When in the alphabet input mode for inputting the alphabetic character in the lower stage, the switching key 12 for the alphabetic character in the upper stage is yellow, and the switching key 12 for the number input mode is pink as shown in FIG. 24.

If the user operates the switching key 12, the control section 7 switches the input mode. At the same time, the control section 7 varies the status of the input keys 10. It also varies the mode of the switching key 12 to another input mode.

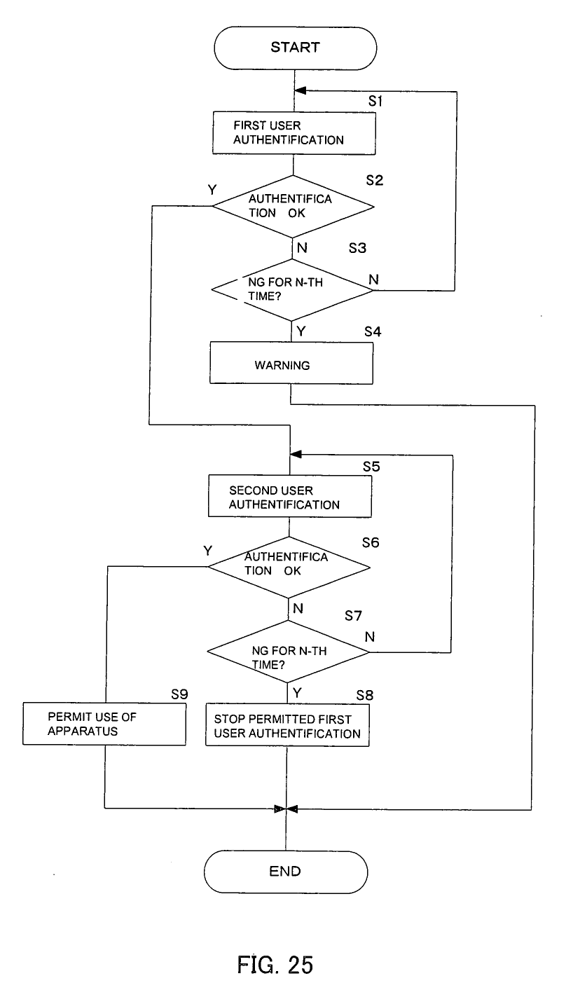

In the case where the input unit performs two-stage authentication, the user can smoothly perform the operation since the status of the input keys 10 is varied. As shown in FIG. 25, to begin with, the user inputs a first password. The authentication section 1 checks the password which is the inputted authentication information (S1). When the first password does not match with the authentication information stored in the storage section 4 (S2), the control section 7 causes a message for prompting reentry to be displayed. In the case where the password cannot be authenticated after inputting the password N times, the control section 7 causes a warning message to be displayed on the display unit 9 (S4).

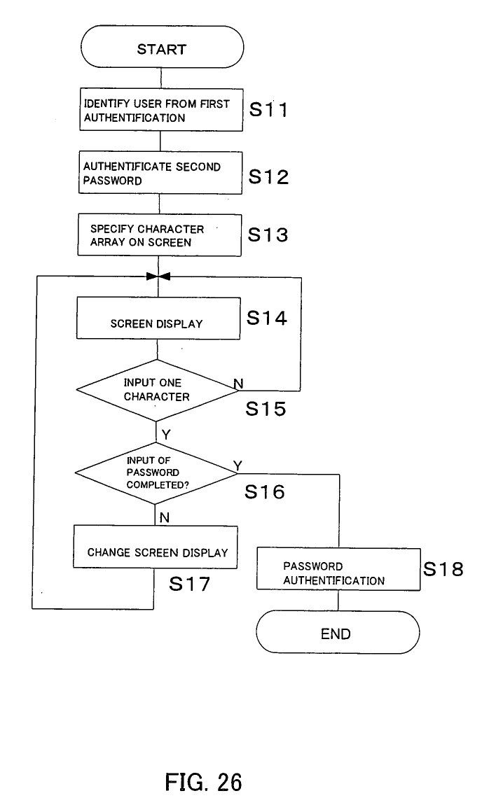

Once the user is authenticated, a next input screen is displayed (S5). In that case, the authenticated user is identified (S11), and the next input contents are predicted (S12) as shown in FIG. 26. Here, a second password is inputted so that the status of the codes of the input keys 10 is varied based on the password (S13).

For instance, the input keys 10 are displayed by varying arrangement of the display sections 11 thereof (S14). The user inputs the password (S15). If a character of the password is inputted (S16), the variable section 13 varies the input keys 10 according to the code to be inputted next (S17).

Once the user finishes inputting the password, the inputted password is checked (S18, S5). If the second password is authenticated (S6), the user is permitted to use the image processing apparatus (S9). In the case where the password cannot be authenticated after inputting the password N times (S7), the user permitted with the first password is inhibited from using the image processing apparatus, and a warning message is displayed on the display unit 9 (S8).

As the case of performing such two-stage authentication, a group such as a department to which the user belongs is identified by first authentication. The user as an individual is identified by second authentication. Or else, the user is identified by the first authentication. The second authentication determines whether or not a process to be executed such as copying or scanning is possible. For instance, a restriction is imposed so that, when processing the confidential documents, the process is not executed unless the second password is inputted. Even if the first password is leaked, leakage of confidential information can be prevented by the second password.

The present invention is not limited to the embodiments. As a matter of course, many modifications and varies may be added to the embodiments within the scope of the invention. The present invention describes the input unit for inputting the password, which is, to be more precise, the operation panel of the image processing apparatus. However, the present invention is not especially limited thereto. For instance, it is applicable to general electronic apparatuses that require the input units for inputting the passwords, such as a facsimile apparatus, a telephone and a cell-phone to which a facsimile number or a telephone number of the other end is inputted when sending a facsimile or making a phone call, the input units used for a cash dispenser, an automated teller machine and the like. It is thereby possible to prevent personal information from being peeped at by a third party.

Variation of the input keys by a variable section is not especially limited thereto. The status of the input keys may also be varied according to the input from the input keys. To be more specific, the status of the input keys is varied when the status of the input keys is operated. In that case, the control section recognizes the contents of the current input process, and predicts the code to be inputted next. And the control section exerts control to vary the status of the input key correspondingly to the code.

The variable section may also vary a pattern and a shape of the input key. To be more precise, when the input key has a pattern, the pattern of the input key is rendered as a shaded pattern in the case of the number input mode. In the case of the alphabet input mode, the pattern of the input key is rendered patchy. When the input keys are formed on the screen section, the shape of the input key is rendered square in the case of the number input mode, and in the case of the alphabet input mode the shape of the input key is rendered circular.

The variable section may also vary the shape of the display sections of the input key according to the input mode. To be more precise, the shape of the display section related to the numeric character is rendered italic, bold or the like in the case of the number input mode. In the case of the alphabet input mode, the shape of the display section related to the alphabetic character is rendered italic, bold or the like.

As a form of varying a part of the input key, the variable section puts only a part of the input key in a different status from other parts. For instance, only a corner of the input key is in a different color, in a different shape or patterned.

The input key is not limited to the one formed on the screen section such as a touch panel, but may also be a hard key. In that case, the input key is an illumination type. The display section of the character or the like formed on the surface of the input key is illuminated in an arbitrary color. The status of the input key is variable by varying the illumination. The input key may include three or more codes. In that case, there are three or more input modes.

It is also possible to unite the notification key and the switching key into a notification and switching key. The notification and switching key is put in the status according to the current input mode. The user can know the input mode from the notification and switching key. If the user operates the notification and switching key, the input mode is switched and the status of the input key varies. At the same time, the notification and switching key also varies to the status according to the input mode after the change.

The first input section may also be a communication interface such as a USB or a biologic information reader instead of the input keys for inputting the passwords. The authentication information is thereby inputted. The first input section and second input section are not limited to the input keys for inputting hiragana, alphanumeric characters and the like but may also be the input keys for selecting the process, such as a copy key of the image processing apparatus, a deposit key and a disbursement key of the automated teller machine. When a specific process is selected by the first input section, the status of the input keys is varied by predicting the second input contents such as the input of the passwords, setup and input of processing conditions according to the specific process. For instance, the color, shape and the like of specific input keys are varied so that the input keys capable of inputting become identifiable out of multiple input keys.

The variable section may vary the pattern and shape of the input keys. To be more precise, when the input key has a pattern, the pattern of the input key is rendered as a shaded pattern in the case of the number input mode. In the case of the alphabet input mode, the pattern of the input key is rendered patchy. When the input keys are formed on the screen section, the shape of the input key is rendered square in the case of the number input mode and in the case of the alphabet input mode. Or else, the shape of the input key is rendered circular.

The variable section may also vary the shape of the display sections of the input key according to the input mode. To be more precise, the shape of the display section related to the numeric character is rendered italic, bold or the like in the case of the number input mode. In the case of the alphabet input mode, the shape of the display section related to the alphabetic character is rendered italic, bold or the like.

As a form of varying a part of the input key, the variable section puts only a part of the input key in a different status from other parts. For instance, only a corner of the input key may be in a different color, in a different shape or patterned.

The variable section may appropriately vary the input mode according to the input contents inputted earlier. In the case of inputting “A13B5” for instance, the variable section starts it in the number input mode, and varies the input mode to the alphabet input mode upon inputting “A.” Thus, the user does not need to switch the input mode each time on inputting input information such as the password in which the numeric characters and the alphabetic characters are mixed. Therefore, input work can be smoothly performed. Moreover, one input key includes multiple input codes so that, even if a third party peeps at it, the third party cannot recognize the input contents. Therefore, security performance can also be improved.

The input key is not limited to the one formed on the screen section such as a touch panel, but may also be a hard key. In that case, the input key is an illumination type. The display section of the character or the like formed on the surface of the input key is illuminated in an arbitrary color. The status of the input key is variable by varying the illumination. The input key may include three or more codes. In that case, there are three or more input modes.

What is claimed is:

1. An input unit comprising:
an input section including input keys having multiple codes; and
a variable section for varying a status of the input keys in order to identify one code out of the multiple codes.

2. The input unit according to claim 1, wherein the variable section varies the entire input key.

3. The input unit according to claim 2, wherein the variable section varies a color of the input key.

4. The input unit according to claim 2, wherein the variable section varies a pattern of the input key.

5. The input unit according to claim 2, wherein the variable section varies a shape of the input key.

6. The input unit according to claim 1, wherein the variable section varies a part of the input key.

7. The input unit according to claim 6, wherein:
there is a display section corresponding to each code formed on the input key; and
the variable section varies the color of the display section of the code.

8. The input unit according to claim 6, wherein:
there is a display section corresponding to each code formed on the input key; and
the variable section varies the shape of the display section of the code.

9. The input unit according to claim 1, wherein the variable section varies each of the multiple input keys to a different status.

10. The input unit according to claim 1, wherein the variable section varies the status of the input key in predetermined timing.

11. The input unit according to claim 10, comprising:
a switching key for switching the status of the input key,
wherein the variable section varies the status of the input key based on an input from the switching key.

12. The input unit according to claim 10, wherein the variable section varies the status of the input key according to an input from the input key.

13. The input unit according to claim 1, comprising a notification section for giving a notice of an inputted code based on the status of the input key.

14. An input unit comprising:
a first input section;
a second input section for inputting through operation by a user;
a determination section for, upon a first input from the first input section, determining contents of the first input; and
a variable section for varying a status of the second input section based on a determination result of the determination section.

15. The input unit according to claim 14, wherein:
the determination section detects the first input from the first input section, and predicts the input from the second input section based on the input contents.

16. The input unit according to claim 15, wherein:
first authentication information is inputted from the first input section; and
second authentication information is inputted from the second input section.

17. The input unit according to claim 14, wherein:
the second input section is an input key whose status varies; and
the first input section inputs information from outside.

18. The input unit according to claim 14, wherein:
the first input section is an input key whose status varies; and
the second input section shares the input key.

19. The input unit according to claim 14, wherein:
the second input section is an input key of which status varies;
the input key includes multiple codes;
the input key has a display section corresponding to each of the codes formed thereon; and
the variable section varies the code and also varies the display section corresponding to the varied code.

20. The input unit according to claim 19, wherein:
the variable section varies the codes of adjacent input keys.

21. The input unit according to claim 14, wherein:
the second input section is an input key whose status varies; and
the variable section varies the status of the input key in predetermined timing after the first input from the first input section.

22. The input unit according to claim 21, comprising:
a switching key for switching the status of the input key,
wherein the variable section varies the status of the input key according to operation of the switching key.

23. The input unit according to claim 21, wherein:
the variable section varies the status of the input key when the input key is operated.

24. The input unit according to claim 14, wherein:
the second input section is an input key whose status varies; and
the variable section varies each of the multiple input keys to a different status.

25. An electronic apparatus comprising the input unit according to any one of claims 1 to 24.

26. The electronic apparatus according to claim 25, wherein:
the electronic apparatus is a copier, a printer, a facsimile, a scanner or a complex apparatus combining two or more of those.
